(19) United States
(12) Patent Application Publication
(10) Pub. No.: US 2025/0120050 A1
(43) Pub. Date: Apr. 10, 2025

(54) CONTAINER AND CONTAINER DATA CENTER

(71) Applicant: BITMAIN TECHNOLOGIES INC., Beijing (CN)

(72) Inventors: Fengjie Li, Beijing (CN); Hangkong Hu, Beijing (CN); Shaoming Huang, Beijing (CN); Yongbo Ge, Beijing (CN); Xiaoxiong Zhang, Beijing (CN); Tuo Geng, Beijing (CN); Tianhao Li, Beijing (CN); Hongshan Zhu, Beijing (CN); Wenkai Cui, Beijing (CN); Minghao Li, Beijing (CN); Shuangquan Hua, Beijing (CN)

(21) Appl. No.: 18/911,122

(22) Filed: Oct. 9, 2024

(30) Foreign Application Priority Data
Oct. 10, 2023 (CN) 202322723117.X

(51) Int. Cl. H05K 7/20

(52) U.S. Cl. CPC H05K 7/20745; H05K 7/20154

(57) ABSTRACT

The present application provides a container and a container data center. The container includes a box, a heat dissipation pipeline, a coil component, a supply component, and an extraction component. The box has an accommodating cavity, and the heat dissipation pipeline, the coil component, the supply component and the extraction component are all located outside the box. The heat dissipation pipeline has an air inlet end and an air outlet end. Two ends of the coil component are respectively connected to the supply component and the extraction component. A cooling medium for cooling high-temperature gas flows inside the coil component and is used to cool the high-temperature gas entering the heat dissipation pipeline from the accommodating cavity. The cooling medium becomes a defective medium after contacting and exchanging heat with the high-temperature gas, and the extraction component is configured to discharge the defective medium.

### CROSS-REFERENCE TO RELATED APPLICATIONS

The present application claims priority to Chinese Application No. 202322723117.X, filed on Oct. 10, 2023, which is hereby incorporated by reference in its entirety.

### TECHNICAL FIELD

The present application relates to the field of data center technology and, in particular, to a container and a container data center.

### BACKGROUND

A container data center refers to a data center that uses containers as its carriers, with the containers housing electronic devices such as server components and the like to form a data center.

In related art, electronic devices such as server components release heat during operations. Cooling of the container data center is generally achieved by directly introducing a cooling medium into the system. The cooling medium exchanges heat with high-temperature air in the containers, thereby reducing their temperature and achieving heat dissipation for electronic devices such as server components within the container data center.

However, the above cooling method has poor cooling effects.

### SUMMARY

In order to solve at least one of the problems mentioned in the background, the present application provides a container and a container data center, aiming to solve the technical problem of poor cooling effect in the cooling method in the related art.

In order to achieve the above objectives, in a first aspect, the present application provides a container including a box, a heat dissipation pipeline, a coil component, a supply component, and an extraction component, the box has an accommodating cavity for housing electronic devices, and the heat dissipation pipeline, the coil component, the supply component, and the extraction component are all located outside the box; the heat dissipation pipeline has an air inlet end and an air outlet end, and both the air inlet end and the air outlet end are connected to the accommodating cavity of the box;
the coil component is located inside the heat dissipation pipeline, and both the supply component and the extraction component are located outside the heat dissipation pipeline; two ends of the coil component are respectively connected to the supply component and the extraction component, and the supply component is configured to provide a cooling medium for the coil component; the coil component has a cooling medium flowing inside;
where the cooling medium becomes a defective medium after heat exchange with a high-temperature gas, and the extraction component is configured to discharge the defective medium.

In the above-mentioned container, in an implementation, the coil component has an inlet pipe, an outlet pipe, and a coil-shaped pipe connecting the inlet pipe and the outlet pipe. The inlet pipe is connected to the supply component, and the outlet pipe is connected to the extraction component;
the coil-shaped pipe has multiple curved pipe segments and multiple straight pipe segments, and any two adjacent curved pipe segments are connected by one straight pipe segment.

In the above-mentioned container, in an implementation, the coil-shaped pipe is a metal pipe, and the curved pipe segment and the straight pipe segment are welded as a single piece.

In the above-mentioned container, in an implementation, the multiple straight pipe segments are parallel to each other and spaced apart at intervals.

In the above-mentioned container, in an implementation, an extension direction of a portion of the heat dissipation pipeline corresponding to the coil component is perpendicular to an extension direction of the straight pipe segment of the coil component.

In the above-mentioned container, in an implementation, along a height direction of the box, the air inlet end and the air outlet end of the heat dissipation pipeline are located on opposite sides of the box, and the air inlet end is located on a side of the air outlet end away from ground;
the coil component is located inside the heat dissipation pipeline and on a side close to the air outlet end.

In the above-mentioned container, in an implementation, the heat dissipation pipeline includes a first sub-pipe, a second sub-pipe and a third sub-pipe connecting the first sub-pipe and the second sub-pipe, and the first sub-pipe and the second sub-pipe are both connected to the box; an end of the first sub-pipe positioning away from the third sub-pipe forms the air inlet end, and an end of the second sub-pipe positioning away from the third sub-pipe forms the air outlet end; the coil component is located inside the second sub-pipe.

In the above-mentioned container, in an implementation, it further includes a fan arranged inside the heat dissipation pipeline, an air outlet of the fan is directed toward at least one of the air inlet end or the air outlet end;
when the air outlet of the fan is directed toward the air inlet end of the heat dissipation pipeline, the fan is configured to transfer a high-temperature gas in the accommodating cavity to the heat dissipation pipeline;
when the air outlet of the fan is directed toward the air outlet end of the heat dissipation pipeline, the fan is configured to transfer a low-temperature gas cooled by the coil component to the accommodating cavity.

In the above-mentioned container, in an implementation, the supply component includes a supply pipe and a supply pump that are interconnected, the supply pipe is connected to the heat dissipation pipeline, and the supply pump is configured to introduce the cooling medium into the heat dissipation pipeline through the supply pipe;
the extraction component includes an extraction pipe and an extraction pump that are interconnected, the outlet pipe is connected to the heat dissipation pipeline, the extraction pump is configured to discharge the defective medium out of the heat dissipation pipeline through the extraction pipe.

In the above container, in an implementation, when the cooling medium is cooling liquid, both the supply pump and the extraction pump are liquid pumps;
alternatively, when the cooling medium is a cooling gas, the supply pump and the extraction pump are both air pumps.

In a second aspect, the present application also provides a container data center, including electronic devices and the container, where the electronic devices are located in the box of the container.

The container and container data center provided in the present application include a box, a heat dissipation pipeline and a coil component. The box has an accommodating cavity for housing electronic devices, and the heat dissipation pipeline has an air inlet end and an air outlet end. The air inlet end and the air outlet end of the heat dissipation pipeline are both connected to the accommodating cavity of the box; the coil component is located inside the heat dissipation pipeline. In this way, the high-temperature gas in the accommodating cavity can enter the heat dissipation pipeline through the air inlet end and pass through the coil component. The coil component can exchange heat with the high-temperature gas and capture the heat of the high-temperature gas, so that the high-temperature gas is converted into a low-temperature gas, which finally enters the accommodating cavity of the container through the air outlet end for cooling electronic devices such as server components, thereby forming a circulating heat process.

The container includes a coil component, a supply component, and an extraction component. The two ends of the coil component are respectively connected to the supply component and the extraction component, the supply component is configured to provide a cooling medium for the coil component. The coil component has a cooling medium flowing inside for cooling a high-temperature gas, which is used to cool the high-temperature gas entering the heat dissipation pipeline from the accommodating cavity. The cooling medium becomes a defective medium after heat exchange with the high-temperature gas, and the extraction component is configured to discharge the defective medium. According to the coil component provided in the heat dissipation pipeline, the coil component has a relatively large cross-sectional area, so its contact area with the high-temperature gas is relatively large, that is, the contact area between the cooling medium and the high-temperature gas is relatively large, thus improving the heat exchange efficiency of the cooling medium and meeting the user's demand for a relatively high heat exchange efficiency of the cooling medium.

The structure of the present application as well as other application purposes and beneficial effects provided by the present application will be more clearly understood through the description of the preferred embodiments in conjunction with the drawings.

### BRIEF DESCRIPTION OF DRAWINGS

In order to explain the technical scheme in embodiments of the present application or the prior art more clearly, the drawings needed to be used in the description of the embodiments or the prior art will be briefly introduced below. Obviously, the drawings in the following description are some embodiments of the present application, and for those skilled in the art, other drawings can be obtained according to these drawings without paying creative effort.

FIG. 1 is a schematic diagram of a three-dimensional structure of a container provided by an embodiment of the present application.

FIG. 2 is a schematic diagram of a partial three-dimensional structure of a container provided by an embodiment of the present application.

FIG. 3 is a schematic diagram of a three-dimensional structure of a coil component of a container provided by an embodiment of the present application.

FIG. 4 is a schematic diagram from a bottom view of a coil component of a container provided by an embodiment of the present application.

### REFERENCE NUMBERS

10—Container; X—First direction; Y—Second direction; Z—Third direction;
100—Box;
200—Heat dissipation pipeline; 201—Air inlet end; 202—Air outlet end;
210—First sub-pipe; 220—Second sub-pipe; 230—Third sub-pipe;
300—Coil component; 310—Inlet pipe; 320—Outlet pipe; 330—Coil-shaped pipe;
331—Curved pipe segment; 332—Straight pipe segment;
400—Supply component; 410—Supply pipe; 500—Extraction component;
510—Extraction pipe; 600—Fan; 700—Supporting component.

Through the above drawings, clear embodiments of the present application has been shown, which will be described in more detail later. These drawings and written descriptions are not intended to limit the scope of the concept of the present application in any way, but to explain the concept of the present application to those skilled in the art by referring to specific embodiments.

### DESCRIPTION OF EMBODIMENTS

In related art, a container is designed with a space for housing electronic devices such as server component(s), and the space is directly connected to a cooling medium via straight pipelines. However, the space of the container is relatively large and the cross-sectional area of the straight pipeline is relatively small, so the contact area between the cooling medium and the space of the container is relatively small, which results in poor heat exchange efficiency of the cooling medium, and cannot meet the user's demand for a relatively high heat exchange efficiency.

Based on the above technical problems, embodiments of the present application provide a container and a container data center, including a box, a heat dissipation pipeline, a coil component, a supply component, and an extraction component. The box has an accommodating cavity for housing electronic devices, and the heat dissipation pipeline has an air inlet end and an air outlet end which are arranged oppositely, the air inlet end and the air outlet end of the heat dissipation pipeline are both connected to the accommodating cavity of the box. The heat dissipation pipeline, the coil component, the supply component, and the extraction component are all located outside the box. In this way, the high-temperature gas in the accommodating cavity can enter the heat dissipation pipeline through the air inlet end and pass through the coil component. The coil component can contact and exchange heat with the high-temperature gas and capture the heat of the high-temperature gas, so that the high-temperature gas is converted into a low-temperature gas, which finally enters the accommodating cavity of the container through the air outlet end for cooling electronic devices such as server components, thereby forming a circulating heat process.

The coil component is located inside the heat dissipation pipeline, and the supply component and the extraction component are both located outside the heat dissipation pipeline. Two ends of the coil component are connected to the supply component and the extraction component respectively. The supply component is configured to provide a cooling medium for the coil component. The coil component has a cooling medium flowing inside for cooling a high-temperature gas, which is used to cool the high-temperature gas entering the heat dissipation pipeline from the accommodating cavity. The cooling medium becomes a defective medium after heat exchange with the high-temperature gas, and the extraction component is configured to discharge the defective medium. Based on the provision of the coil component, the coil component has a relatively large cross-sectional area, so its contact area with the high-temperature gas is relatively large, that is, the contact area between the cooling medium and the high-temperature gas is relatively large, thus improving the heat exchange efficiency of the cooling medium and meeting the user's demand for a relatively high heat exchange efficiency of the cooling medium.

In order to make the purpose, technical scheme and advantages of this application more clear, the technical scheme in the embodiments of this application will be described in more detail with the drawings in the preferred embodiments of the present application. In the drawings, the same or similar reference numerals indicate the same or similar structural members or structural members with the same or similar functions throughout. The described embodiments is part of structural embodiments of the present application, not all of the structural embodiments. The embodiments described below by referring to the drawings are exemplary and are intended to explain the preset application, but not to be construed as limitations of the present application. Based on the embodiments in this application, all other embodiments obtained by those skilled in the art without creative effort belong to the protection scope of this application. Hereinafter, embodiments of the present application will be described in detail with reference to the drawings.

In a first aspect, an embodiment of the present application provides a container data center, including electronic devices and a container, where the electronic devices are located in a box of the container.

It is understandable that the number of electronic devices can be arbitrary. For example, the number of electronic devices can be two, three, four, five, etc. The embodiments of the present application do not limit the specific number of electronic devices, nor are they limited to the above examples.

It should be noted that the electronic device can be a server, a personal computer, a mobile phone, or an electronic component with different functions, such as a battery with a power supply function, a memory with a storage function, etc. The embodiments of the present application do not limit the specific form of the electronic device, nor are they limited to the above examples.

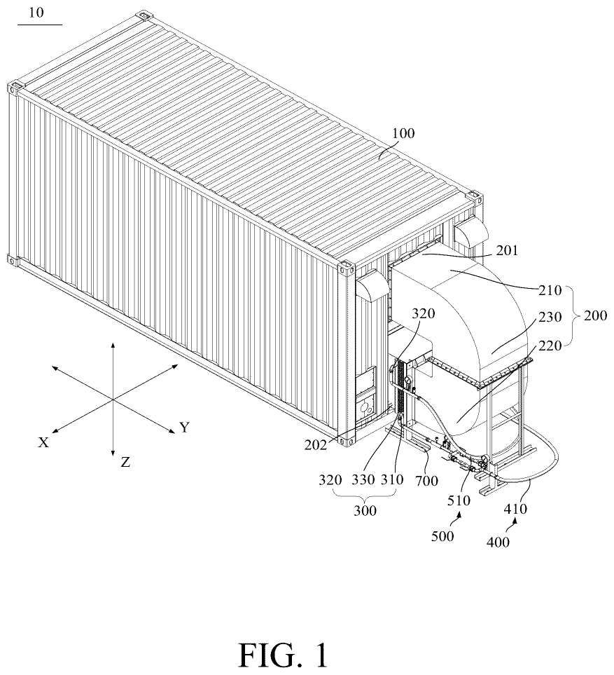

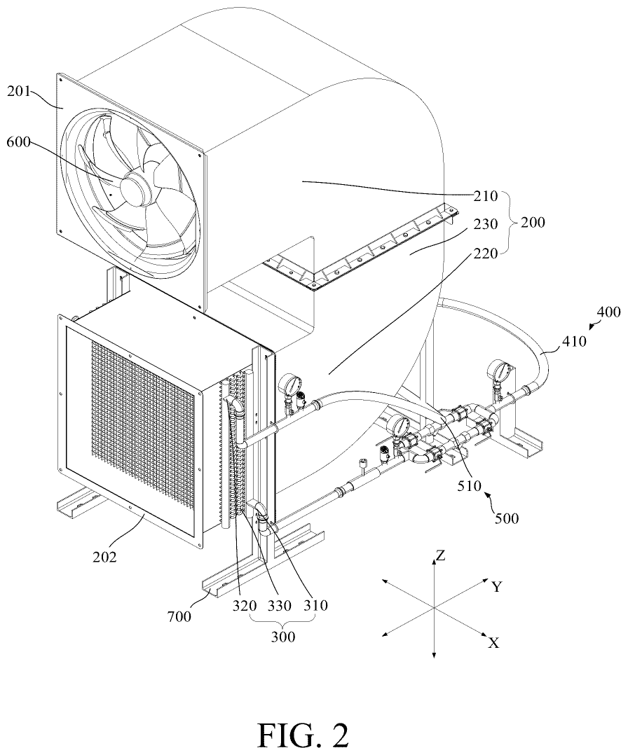

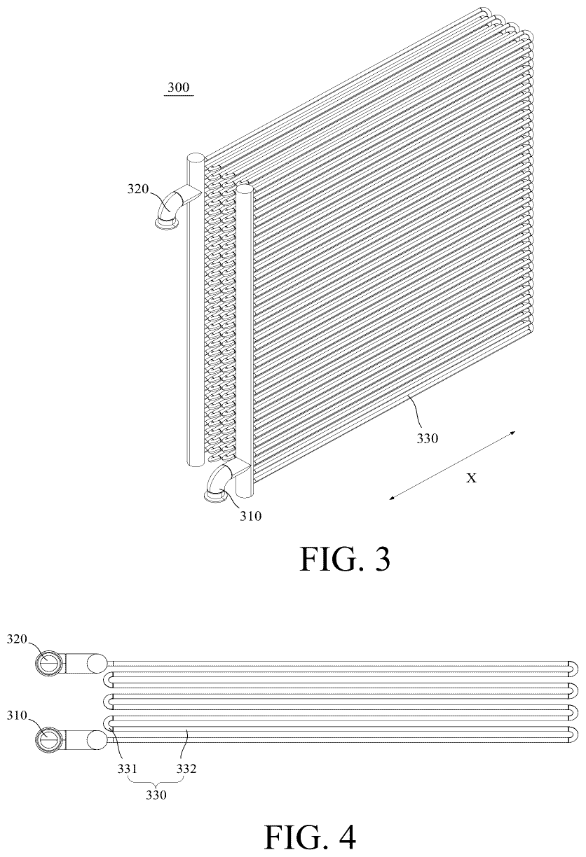

FIG. 1 is a schematic diagram of a three-dimensional structure of a container provided by an embodiment of the present application; FIG. 2 is a schematic diagram of a partial three-dimensional structure of a container provided by an embodiment of the present application; FIG. 3 is a schematic diagram of a three-dimensional structure of a coil component of a container provided by an embodiment of the present application; FIG. 4 is a schematic diagram from a bottom view of a coil component of a container provided by an embodiment of the present application.

In the second aspect, referring to FIG. 1, an embodiment of the present application further provides a container 10, including a box 100, a heat dissipation pipeline 200, a coil component 300, a supply component 400 and an extraction component 500.

Specifically, the box 100 has an accommodating cavity 101 for housing electronic devices. The shape of the box 100 can be arbitrary, for example, the shape of the box 100 can be a cube, a cylinder, a triangular prism, etc. The embodiments of the present application do not limit the specific shape of the box 100, nor are they limited to the above examples.

In the following, description will be made by taking the case where the box 100 is in the shape of a rectangular parallelepiped as an example.

Further, referring to FIG. 1, the heat dissipation pipeline 200, the coil component 300, the supply component 400 and the extraction component 500 are all located outside box 100, and the heat dissipation pipeline 200 has an air inlet end 201 and an air outlet end 202, and the air inlet end 201 and the air outlet end 202 are both connected to the accommodating cavity 101 of the box 100; that is, the high-temperature gas in the box 100 can enter the heat dissipation pipeline 200 through the air inlet end 201, and the low-temperature gas in the heat dissipation pipeline 200 can enter the box 100 through the air outlet end 202, so as to facilitate heat exchange and cooling of the electronic devices located in the box 100.

The coil component 300 is located inside the heat dissipation pipeline 200, and the supply component 400 and the extraction component 500 are both located outside the heat dissipation pipeline 200. The two ends of the coil component 300 are respectively connected to the supply component 400 and the extraction component 500. The supply component 400 is configured to provide a cooling medium for the coil component 300. The cooling medium flows inside the coil component 300, and the cooling medium can be used to cool the high-temperature gas entering the heat dissipation pipeline 200 from the accommodating cavity 101.

It should be noted that the coil component 300 has a relatively large cross-sectional area, that is, the contact area between the coil component 300 and the high-temperature gas is relatively large. Therefore, when the cooling medium flows inside the coil component 300, the superimposed contact area between the cooling medium and the high-temperature gas is relatively large, which can improve the heat exchange efficiency of the cooling medium and meet the user's demand for a relatively high heat exchange efficiency of the cooling medium.

The cooling medium becomes a defective medium after heat exchange with the high-temperature gas, and the extraction component 500 is configured to discharge the defective medium. It can be understood that heat exchange between the cooling medium and the high-temperature gas can be achieved in a way of contact heat exchange. After the contact heat exchange, the temperature of the cooling medium becomes lower and is transformed into a defective medium. After the high-temperature gas and the cooling medium are contacted for heat exchange, the high-temperature gas is converted into a low-temperature gas. The low-temperature gas can be contacted with the electronic devices located in the accommodating cavity 101 for heat exchange to achieve heat dissipation of the electronic devices and form a heat dissipation cycle.

As a possible implementation, referring to FIG. 3 and FIG. 4, the coil component 300 has an inlet pipe 310, an outlet pipe 320, and a coil-shaped pipe 330 connecting the inlet pipe 310 and the outlet pipe 320, the inlet pipe 310 is connected to the supply component 400, and the outlet pipe 320 is connected to the extraction component 500. The coil-shaped pipe 330 has multiple curved pipe segments 331 and multiple straight pipe segments 332, and any two adjacent curved pipe segments 331 are connected by a straight pipe segment 332.

The arrangement of the coil-shaped pipe 330 having multiple curved pipe segments 331 and multiple straight pipe segments 332 allows for a relatively large area of the coil-shaped pipe 330, and thus the coil component 300 has a relatively large area. That is, the contact area between the coil component 300 and the high-temperature gas is relatively large, and thus when the cooling medium flows inside the coil component 300, the contact area between the cooling medium and the high-temperature gas is relatively large, which can improve the heat exchange efficiency of the cooling medium and meet the user's demand for a relatively high heat exchange efficiency of the cooling medium.

As a possible implementation, the coil-shaped pipe 330 is a metal pipe, and the curved pipe segment 331 and the straight pipe segment 332 are welded into an integral piece. The arrangement of the metal coil-shaped pipe 330 allows for a higher thermal conductivity of the metal pipe, so that the heat exchange efficiency of the coil-shaped pipe 330 becomes higher. In addition, the arrangement of the curved pipe segment 331 and the straight pipe segment 332 being welded into an integral piece allows for a higher structural strength of the coil-shaped pipe 330.

Further, multiple curved pipe segments 331 and multiple straight pipe segments 332 can be formed into an integral piece by welding. In this case, the connection tightness at each position in the coil-shaped pipe 330 is good, and the risk of cooling medium leakage is low.

As a possible implementation, multiple straight pipe segments 332 are parallel to each other and spaced apart at intervals. In this way, multiple straight pipe segments 332 can be evenly covered in the heat dissipation pipeline 200, and the contact area between the cooling medium and the straight pipe segment 332 is large, which can improve the heat exchange efficiency of the cooling medium and meet the user's demand for a relatively high heat exchange efficiency of the cooling medium.

As a possible implementation, an extension direction of a portion of the heat dissipation pipeline 200 corresponding to the coil component 300 is perpendicular to an extension direction of the coil component 300. For example, as shown in FIG. 1 and FIG. 2, the extension direction of the coil component 300 is the first direction X, and the extension direction of the portion of the heat dissipation pipeline 200 corresponding to the coil component 300 is the second direction Y, where the first direction X is perpendicular to the second direction Y. At this time, the area passed by the gas flowing through the coil component 300 in the heat dissipation pipeline 200 is the largest. Therefore, the contact area between the coil component 300 and the high-temperature gas is relatively large, which can improve the heat exchange efficiency of the cooling medium and meet the user's demand for a relatively high heat exchange efficiency of the cooling medium.

As a possible implementation, referring to FIG. 1 and FIG. 2, along the height direction of the box 100, that is, along the third direction Z, the air inlet end 201 and the air outlet end 202 of the heat dissipation pipeline 200 are located on opposite sides of the box 100, respectively. The air inlet end 201 is located on a side of the air outlet end 202 away from the ground; the coil component 300 is located inside the heat dissipation pipeline 200 and on a side near the air outlet end 202.

Through the above-mentioned arrangement, the flow path of the low-temperature gas in the heat dissipation pipeline 200 can be shortened, the time required for the low-temperature gas to enter the box 100 from the heat dissipation pipeline 200 through the air outlet end 202 is shorter, and the time required for the electronic devices to contact with the low-temperature gas is shorter, which can improve the heat exchange efficiency of the electronic devices, thereby helping to meet the user's demand for a relatively high heat exchange efficiency of the cooling medium.

As a possible implementation, referring to FIG. 1 and FIG. 2, the heat dissipation pipeline 200 includes a first sub-pipe 210, a second sub-pipe 220, and a third sub-pipe 230 that connects the first sub-pipe 210 with the second sub-pipe 220. Both the first sub-pipe 210 and the second sub-pipe 220 are connected to the box 100. An end of the first sub-pipe 210 positioning away from the third sub-pipe 230 forms the air inlet end 201, and an end of the second sub-pipe 220 positioning away from the third sub-pipe 230 forms the air outlet end 202; the coil component 300 is located inside the second sub-pipe 220.

Referring to FIG. 1 and FIG. 2, the first sub-pipe 210 and the second sub-pipe 220 can extend along the second direction Y, and the third sub-pipe 230 extends along the third direction Z.

Through the above-mentioned arrangement, the flow path of the low-temperature gas in the heat dissipation pipeline 200 can be shortened, the time required for the low-temperature gas to enter the box 100 from the heat dissipation pipeline 200 through the air outlet end 202 is shorter, and the time required for the electronic devices to contact with the low-temperature gas is shorter, which can improve the heat exchange efficiency of the electronic devices, thereby helping to meet the user's demand for a relatively high heat exchange efficiency of the cooling medium.

As a possible implementation, a fan 600 is further included, the fan 600 is located inside the heat dissipation pipeline 200. It should be understood that the fan 600 can be an axial flow fan, with its air inlet and air outlet located on opposite sides of the axis. The air outlet of the fan 600 is directed towards at least one of the air inlet end 201 or the air outlet end 202.

Exemplarily, the air outlet of the fan 600 may be directed only toward the air inlet end 201 of the heat dissipation pipeline 200, or may be directed only toward the air outlet end 202 of the heat dissipation pipeline 200. In addition, the number of fans 600 may be two, and the air outlets of the two fans 600 may be directed toward the air inlet end 201 and the air outlet end 202 of the heat dissipation pipeline 200, respectively.

Further, referring to FIG. 2, when the air outlet of the fan 600 is directed toward the air inlet end 201 of the heat dissipation pipeline 200, the fan 600 is configured to transfer the high-temperature gas in the accommodating cavity 101 to the heat dissipation pipeline 200. In this way, the time required for the high-temperature gas to enter the heat dissipation pipeline 200 through the air inlet end 201 is shorter, and the time required for the high-temperature gas to pass through the coil component 300 is shorter, and then the time required for the coil component 300 to form the low-temperature gas is shorter, which can improve the heat exchange efficiency of the coil component 300, and then improve the heat exchange efficiency of the electronic devices, thereby helping to meet the user's demand for a relatively high heat exchange efficiency of the cooling medium.

Further, when the air outlet of the fan 600 is directed toward the air outlet end 202 of the heat dissipation pipeline 200, the fan 600 is configured to transfer the cooled low-temperature gas to the accommodating cavity 101. In this way, the time required for the low-temperature gas to enter the box 100 through the air outlet end 202 is shorter, the flow path of the low-temperature gas in the heat dissipation pipeline 200 can be shortened, the time required for the low-temperature gas to enter the box 100 from the heat dissipation pipeline 200 through the air outlet end 202 is shorter, and the time required for the electronic devices to contact with the low-temperature gas is shorter, which can improve the heat exchange efficiency of the electronic devices, thereby helping to meet the user's demand for a relatively high heat exchange efficiency of the cooling medium.

As a possible implementation, a supporting component 700 is further included, and the supporting component 700 is configured to support the heat dissipation pipeline 200. Specifically, the supporting component 700 may be sleeved on the second sub-pipe 220 of the heat dissipation pipeline 200 to support the heat dissipation pipeline 200 and ensure stable operations of the heat dissipation pipeline 200.

It is understandable that the supporting component 700 may also be sleeved on the coil component 300 to ensure that the coil component 300 can be well connected to the heat dissipation pipeline 200.

As a possible implementation, referring to FIG. 1 and FIG. 2, the supply component 400 includes a supply pipe 410 and a supply pump (not shown in the figures) that are interconnected, the supply pipe 410 is connected to the heat dissipation pipeline 200, and the supply pump is configured to introduce the cooling medium into the heat dissipation pipeline 200 through the supply pipe 410. Among them, one end of the supply pipe 410 can be connected to the inlet pipe 310 of the coil component 300, and the other end of the supply pipe 410 can be connected to the supply pump. The cooling medium provided by the supply pump can enter the inlet pipe 310 through the supply pipe 410 and then enter the coil-shaped pipe 330.

Further, the extraction component 500 includes an extraction pipe 510 and an extraction pump (not shown in the figures) that are interconnected. The extraction pipe 510 is connected to the heat dissipation pipeline 200, and the extraction pump is configured to discharge the defective medium out of the heat dissipation pipeline 200 through the extraction pipe. Among them, one end of the extraction pipe 510 can be connected to the outlet pipe 320 of the coil component 300, and the other end can be connected to the extraction pump. The extraction pump can provide suction, so that the defective medium in the coil component 300 can enter the extraction pipe 510 through the outlet pipe 320, and then be discharged out of the heat dissipation pipeline 200.

Through the above arrangement, the supply pump can deliver the cooling medium to the heat dissipation pipeline 200 through the supply pipe 410 to replenish the consumed cooling medium. The extraction pump can discharge the defective medium out of the heat dissipation pipeline 200 through the extraction pipe 510, so as to provide space for the cooling medium.

As a possible implementation, the supply pump is a liquid pump for supplying cooling liquid, and the extraction pump is a liquid pump for discharging defective liquid, that is, the cooling medium is cooling liquid. Exemplarily, the cooling liquid may include calcium chloride or methanol or ethanol or ethylene glycol or pure water.

As a possible implementation, the supply pump is an air pump for supplying cooling gas, and the extraction pump is an air pump for discharging defective gas, that is, the cooling medium is a cooling gas. Exemplarily, the cooling gas may include Freon or propane or butane or methane or carbon dioxide.

It should be noted that the embodiments of the present application do not limit the type and category of the cooling medium, nor are they limited to the above examples.

In the description of the embodiments of the present application, it should be understood that unless otherwise specified and limited, the terms “installation”, “connected with” and “connection” should be broadly understood, for example, they can be fixed connection, indirect connection through an intermediary, structural communication between two elements or interactive relationship between two elements. For those skilled in the art, the specific meanings of the above terms in this application can be understood according to the specific circumstances.

The orientations or positional relationships indicated by the terms “upper”, “lower”, “front”, “rear”, “vertical”, “horizontal”, “top”, “bottom”, “inner” and “outer” are orientations or positional relationships based on the drawings, which is only for the convenience of describing the present application and simplifying the description, and does not indicate or imply that the devices or elements referred to must have a specific orientation, be constructed and operated in a specific orientation, and therefore should not be construed as a limitation of this application. In the description of this application, “a plurality of” means two or more, unless it is precisely specified otherwise.

The terms “first”, “second”, “third” and “fourth” in the specification and claims of this application and the above drawings are used to distinguish similar objects, and are not necessarily used to describe a specific order or sequence. It should be understood that such data are interchangeable under appropriate circumstances, so that the embodiments of the present application described herein can be implemented in other orders than those illustrated or described herein. Furthermore, the terms “including” and “having” and any variations thereof are intended to cover non-exclusive inclusion, for example, a process, method, system, product or device that includes a series of steps or units is not necessarily limited to those explicitly listed, but may include other steps or units not explicitly listed or inherent to such process, method, product or device.

Finally, it should be explained that the above embodiments are only used to illustrate the technical scheme of the present application, but not to limit it. Although the present application has been described in detail with reference to the foregoing embodiments, it should be understood by those skilled in the art that the technical scheme described in the foregoing embodiments can still be modified, or the technical features of structural parts or full structures can be replaced by equivalents. However, these modifications or substitutions do not make the essence of the corresponding technical solutions deviate from the scope of the technical solutions of various embodiments of this application.

What is claimed is:

1. A container, comprising a box, a heat dissipation pipeline, a coil component, a supply component, and an extraction component, the box has an accommodating cavity for housing electronic devices, and the heat dissipation pipeline, the coil component, the supply component, and the extraction component are all located outside the box; the heat dissipation pipeline has an air inlet end and an air outlet end, and both the air inlet end and the air outlet end are connected to the accommodating cavity of the box;
the coil component is located inside the heat dissipation pipeline, and both the supply component and the extraction component are located outside the heat dissipation pipeline; two ends of the coil component are respectively connected to the supply component and the extraction component, the supply component is configured to provide a cooling medium for the coil component, and the coil component has a cooling medium flowing inside;
wherein the cooling medium becomes a defective medium after heat exchange with a high-temperature gas, and the extraction component is configured to discharge the defective medium.

2. The container according to claim 1, wherein the coil component has an inlet pipe, an outlet pipe, and a coil-shaped pipe connecting the inlet pipe and the outlet pipe, the inlet pipe is connected to the supply component, and the outlet pipe is connected to the extraction component;
the coil-shaped pipe has multiple curved pipe segments and multiple straight pipe segments, and any two adjacent curved pipe segments are connected by a straight pipe segment.

3. The container according to claim 2, wherein the coil-shaped pipe is a metal pipe, and the curved pipe segment and the straight pipe segment are welded as a single piece.

4. The container according to claim 2, wherein the multiple straight pipe segments are parallel to each other and spaced apart at intervals.

5. The container according to claim 2, wherein an extension direction of a portion of the heat dissipation pipeline corresponding to the coil component is perpendicular to an extension direction of the straight pipe segment of the coil component.

6. The container according to claim 1, wherein along a height direction of the box, the air inlet end and the air outlet end of the heat dissipation pipeline are located on opposite sides of the box, and the air inlet end is located on a side of the air outlet end away from ground;
the coil component is located inside the heat dissipation pipeline and on a side close to the air outlet end.

7. The container according to claim 1, wherein the heat dissipation pipeline comprises a first sub-pipe, a second sub-pipe and a third sub-pipe connecting the first sub-pipe and the second sub-pipe, and the first sub-pipe and the second sub-pipe are both connected to the box; an end of the first sub-pipe positioning away from the third sub-pipe forms the air inlet end, and an end of the second sub-pipe positioning away from the third sub-pipe forms the air outlet end; the coil component is located inside the second sub-pipe.

8. The container according to claim 1, further comprising a fan arranged in the heat dissipation pipeline, an air outlet of the fan is directed toward at least one of the air inlet end or the air outlet end;
when the air outlet of the fan is directed toward the air inlet end of the heat dissipation pipeline, the fan is configured to transfer a high-temperature gas in the accommodating cavity to the heat dissipation pipeline;
when the air outlet of the fan is directed toward the air outlet end of the heat dissipation pipeline, the fan is configured to transfer a low-temperature gas cooled by the coil component to the accommodating cavity.

9. The container according to claim 1, wherein the supply component comprises a supply pipe and a supply pump that are interconnected, the supply pipe is connected to the heat dissipation pipeline, and the supply pump is configured to introduce the cooling medium into the heat dissipation pipeline through the supply pipe;
the extraction component comprises an extraction pipe and an extraction pump that are interconnected, the extraction pipe is connected to the heat dissipation pipeline, the extraction pump is configured to discharge the defective medium out of the heat dissipation pipeline through the extraction pipe.

10. A container data center, comprising electronic devices and the container, wherein the electronic devices are located inside the box of the container;
wherein the container comprises a box, a heat dissipation pipeline, a coil component, a supply component, and an extraction component, the box has an accommodating cavity for housing electronic devices, and the heat dissipation pipeline, the coil component, the supply component, and the extraction component are all located outside the box; the heat dissipation pipeline has an air inlet end and an air outlet end, and both the air inlet end and the air outlet end are connected to the accommodating cavity of the box;
the coil component is located inside the heat dissipation pipeline, and both the supply component and the extraction component are located outside the heat dissipation pipeline; two ends of the coil component are respectively connected to the supply component and the extraction component, the supply component is configured to provide a cooling medium for the coil component, and the coil component has a cooling medium flowing inside;
wherein the cooling medium becomes a defective medium after heat exchange with a high-temperature gas, and the extraction component is configured to discharge the defective medium.

11. The container data center according to claim 10, wherein the coil component has an inlet pipe, an outlet pipe, and a coil-shaped pipe connecting the inlet pipe and the outlet pipe, the inlet pipe is connected to the supply component, and the outlet pipe is connected to the extraction component;
the coil-shaped pipe has multiple curved pipe segments and multiple straight pipe segments, and any two adjacent curved pipe segments are connected by a straight pipe segment.

12. The container data center according to claim 10, wherein the coil-shaped pipe is a metal pipe, and the curved pipe segment and the straight pipe segment are welded as a single piece.

13. The container data center according to claim 10, wherein the multiple straight pipe segments are parallel to each other and spaced apart at intervals.

14. The container data center according to claim 10, wherein an extension direction of a portion of the heat dissipation pipeline corresponding to the coil component is perpendicular to an extension direction of the straight pipe segment of the coil component.

15. The container data center according to claim 10, wherein along a height direction of the box, the air inlet end and the air outlet end of the heat dissipation pipeline are located on opposite sides of the box, and the air inlet end is located on a side of the air outlet end away from ground;
the coil component is located inside the heat dissipation pipeline and on a side close to the air outlet end.

16. The container data center according to claim 10, wherein the heat dissipation pipeline comprises a first sub-pipe, a second sub-pipe and a third sub-pipe connecting the first sub-pipe and the second sub-pipe, and the first sub-pipe and the second sub-pipe are both connected to the box; an end of the first sub-pipe positioning away from the third sub-pipe forms the air inlet end, and an end of the second sub-pipe positioning away from the third sub-pipe forms the air outlet end; the coil component is located inside the second sub-pipe.

17. The container data center according to claim 10, wherein the container further comprises a fan arranged in the heat dissipation pipeline, an air outlet of the fan is directed toward at least one of the air inlet end or the air outlet end;
when the air outlet of the fan is directed toward the air inlet end of the heat dissipation pipeline, the fan is configured to transfer a high-temperature gas in the accommodating cavity to the heat dissipation pipeline;
when the air outlet of the fan is directed toward the air outlet end of the heat dissipation pipeline, the fan is configured to transfer a low-temperature gas cooled by the coil component to the accommodating cavity.

18. The container data center according to claim 10, wherein the supply component comprises a supply pipe and a supply pump that are interconnected, the supply pipe is connected to the heat dissipation pipeline, and the supply pump is configured to introduce the cooling medium into the heat dissipation pipeline through the supply pipe;
the extraction component comprises an extraction pipe and an extraction pump that are interconnected, the extraction pipe is connected to the heat dissipation pipeline, the extraction pump is configured to discharge the defective medium out of the heat dissipation pipeline through the extraction pipe.
